(19) United States
(12) Patent Application Publication
(10) Pub. No.: US 2026/0188562 A1
(43) Pub. Date: Jul. 2, 2026

(54) Inductors Embedded in Package Substrate and Board and Method and System for Manufacturing the Same

(71) Applicant: Chipletz, Inc., Spicewood, TX (US)

(72) Inventors: Siddharth Ravichandran, Austin, TX (US); Michael Su, Austin, TX (US); Michael Alfano, Austin, TX (US); Bryan Black, Spicewood, TX (US)

(73) Assignee: Chipletz, Inc., Spicewood, TX (US)

(21) Appl. No.: 19/548,050

(22) Filed: Feb. 24, 2026

Related U.S. Application Data
(62) Division of application No. 18/206,933, filed on Jun. 7, 2023.
(60) Provisional application No. 63/349,920, filed on Jun. 7, 2022.

(51) Int. Cl. H01F 27/28; H01F 27/245; H01F 27/32; H01F 41/00; H01F 41/07; H01F 41/071; H01F 41/10; H01F 41/14; H10D 1/20; H10W 70/05; H10W 70/60; H10W 70/65

(52) U.S. Cl. CPC H01F 27/2828; H01F 27/245; H01F 27/327; H01F 41/005; H01F 41/07; H01F 41/071; H01F 41/10; H01F 41/14; H10D 1/20; H10W 70/05; H10W 70/611; H10W 70/65

(57) ABSTRACT

A semiconductor package substrate with embedded passive devices and methods of forming the same is provided. Embedded passive devices include inductors and inductor modules and methods of forming the same are provided. Embedded inductors may be formed by deposition of magnetic core material, trenching of one or more channels, and placement of conductive wires to form an module embeddable in the semiconductor package substrate core. Provided are methods and apparatus for formation of embeddable pot-core, toroidal, and helical inductors.

### CROSS-REFERENCE TO RELATED APPLICATIONS

This application is related to the following:
1. Provisional Application Ser. No. 63/349,920, filed 7 Jun. 2022 (“Parent Provisional”); and
2. U.S. application No. Ser. No. 18/206,933, filed 7 Jun. 2023 (“Parent Application”).

This application is:
a Divisional Application of the Parent Application;
which in turn claims priority to the Parent Provisional
This application claims priority to the Parent Application and Parent Provisional, collectively “Priority References”, and hereby claims benefit of the filing date thereof pursuant to 37 C.F.R. § 1.78(a).

The subject matter of the Priority References, each in their respective entirety, are expressly incorporated herein by reference.

### FIELD OF INVENTION

Embodiments of the present invention are directed to semiconductor packaging and, more particularly, to improve performance and reduce area by utilizing an embedded inductor approach where prefabricated inductors are integrated in the AC/DC substrate that may have a fine-pitch routing, and/or may have a few coarse-pitch layers.

### BACKGROUND

In general, in the descriptions that follow, the first occurrence of each special term of art that should be familiar to those skilled in the art of integrated circuits (“ICs”) and systems will be italicized. In addition, when a term that may be new or that may be used in a context that may be new, that term will be set forth in bold and at least one appropriate definition for that term will be provided. Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

Integrated circuit (“IC”) packages may include multiple dies, passive components, and a package substrate. The package substrate may include one or more dielectric layers and a one or more of interconnects and/or interconnecting layers. The package substrate may be a laminated substrate. The interconnects may include traces, pads and/or vias. The dies may be coupled to the package substrate through solder balls and the like. The package substrate may be coupled to a printed circuit board (“PCB”) through solder balls and the like. An inductor may be mounted on the PCB. The inductor may be located externally to the IC package, and takes up a lot real estate on the PCB.

One drawback of an inductor located externally to the IC package is that it creates a device with a form factor that may be too large for the needs of mobile computing devices, wearable computing devices, or other platforms that require small form computing devices. This may result in a device that is either too large and/or too thick. That is, the combination of the IC package, the inductor, and the PCB may be too thick and/or have a surface area that is too large to meet the needs and/or requirements of mobile computing devices, wearable computing devices, or other platforms that require small form computing devices. Traditional inductors are bulky, single-sided, being designed for board mounting where power is delivered from one end of the board to the package substrate, and hence cannot be embedded in semiconductor substrates.

Therefore, there is a need for an IC package or substrate that includes an inductor, where the IC package or substrate has a better form factor, while at the same time meeting the needs and/or requirements of mobile computing devices, wearable computing devices, or other platforms that require small form computing devices. High-performance computing applications require power efficiency which is commonly achieved by reducing the losses between voltage conversion module and the dies. These applications also require smaller inductors that can be brough closer to the dies, along with double-sided terminals to enable superior vertical power delivery paths. In particular, we submit that such a method and apparatus should provide performance generally comparable to the best prior art techniques but more efficiently than known implementations of such prior art techniques.

### BRIEF SUMMARY OF THE INVENTION

According to a different embodiment, an inductor adapted for use in a semiconductor package, the inductor comprising: a substrate core; a plurality of trenches in the substrate core; a conductive material deposited in the plurality of trenches in the substrate core; a first insulative layer on a first surface of the substrate core and a first surface of the conductive material deposited in the plurality of trenches in the substrate core; an inductive pattern formed by at least: a first via hole, beginning at a surface of the first insulative layer, through the first insulative layer, terminating at the first surface of the conductive material deposited in the plurality of trenches in the substrate core; a second insulative layer on the surface of the first insulative layer and in the first via hole; and a second via hole, beginning at a surface of the second insulative layer, through the second insulative layer, terminating at the first surface of the conductive material deposited in the plurality of trenches in the substrate core.

According to yet a different embodiment, a sheet of thin-film pot-core inductors comprising: a substrate core material; a first magnetic material deposited on a portion of an area of the substrate core material; a first plurality of inductors formed by a first plurality of trenches in the substrate core material and in the first magnetic material, the first plurality of trenches being filled with conductive material; and a second plurality of trenches in the substrate core and in the first magnetic material, the second plurality of trenches being filled with insulative material; the second plurality of trenches being interleaved between the first plurality of trenches to control coupling between the first plurality of inductors.

### BRIEF DESCRIPTION OF THE SEVERAL VIEWS OF THE DRAWINGS

FIG. 1 illustrates, in diagrammatic form, a cut-away side view of an IC package substrate in accordance with some embodiments;

FIG. 2 illustrates, in diagrammatic form, a cut-away side view of a package substrate using package substrate redistribution layers (“RDL”) traces, in accordance with some embodiments;

FIG. 3 illustrates, in diagrammatic form, a top view of a package substrate using package substrate RDL layers traces, in accordance with some embodiments;

FIG. 4 illustrates, in diagrammatic form, a top view of a package substrate using package substrate RDL layers traces, in accordance with some embodiments;

FIG. 5 illustrates, in diagrammatic form, a cut-away side view of a fabrication process of a thin-film strip inductor using cylindrical and rectangular wires in a thin-film form, in accordance with some embodiments;

FIG. 6 illustrates, in flow chart form, a fabrication method of the fabrication process of a thin-film strip inductor using cylindrical and rectangular wires in a thin-film form as illustrated in FIG. 5, in accordance with some embodiments;

FIG. 7 illustrates, in diagrammatic form, a technique for connecting to an embedded pot core conductor within a thin film strip inductor 700, in accordance with some embodiments;

FIG. 8 illustrates, in diagrammatic form, a cut-away side view of a technique for connecting to an embedded pot core conductor within a thin film strip inductor, in accordance with some embodiments;

FIG. 9 illustrates, in flow chart form, a method of connecting to an embedded pot core conductor within a thin film strip inductor as illustrated in FIG. 8, in accordance with some embodiments;

FIG. 10 illustrates, in diagrammatic form, a cut-away side view of a technique for connecting to an embedded pot core conductor within a thin film strip inductor, in accordance with some embodiments;

FIG. 11 illustrates, in flow chart form, a method of connecting to an embedded pot core conductor within a thin film strip inductor as illustrated in FIG. 10, in accordance with some embodiments;

FIG. 12 illustrates, in diagrammatic form, a top view of a process for forming connections to and isolations between embedded pot core inductors on a sheet of embedded pot core inductors, in accordance with some embodiments;

FIG. 13 illustrates, in flow chart form, a method for forming connections to and isolations between embedded pot core inductors on a sheet of embedded pot core inductors as illustrated in FIG. 12, in accordance with some embodiments;

FIG. 14 illustrates, in diagrammatic form, a process of mitigating inductor coupling using trenching, in accordance with some embodiments;

FIG. 15 illustrates, in diagrammatic form, a sheet of thin-film inductors using multi-layer thin-film sheets of magnetic material to alternate the flux direction of the thin-film inductors, in accordance with some embodiments;

FIG. 16 illustrates, in diagrammatic form, exemplary stacked embedded inductors in a substrate core, in accordance with some embodiments;

FIG. 17 illustrates, in diagrammatic form, a process for using pot-core strip inductors to build vertical inductors, in. accordance with some embodiments;

FIG. 18 illustrates, in diagrammatic form, a substrate core with vertical inductors embedded in cavity, in accordance with some embodiments;

FIG. 19 illustrates, in diagrammatic form, an exemplary N-racetrack coupled pot-core strip inductor, in accordance with some embodiments;

FIG. 20 illustrates, in diagrammatic form, other exemplary N-racetrack coupled pot-core strip inductor, in accordance with some embodiments;

FIG. 21 illustrates, in diagrammatic form, a top view of a single sheet of pot core strip inductors, in accordance with some embodiments;

FIG. 22 illustrates, in diagrammatic form, a top view of a single sheet of pot core strip inductors, in accordance with some embodiments;

FIG. 23 illustrates, in diagrammatic form, an exemplary multi-layer pot-core coil inductor, in accordance with some embodiments;

FIG. 24 illustrates, in diagrammatic form, a different exemplary multi-layer pot-core coil inductor, in accordance with some embodiments;

FIG. 25 illustrates, in diagrammatic form, a different exemplary multi-layer pot-core coil inductor, in accordance with some embodiments;

FIG. 26 illustrates, in diagrammatic form, a cut-away side view of a fabrication process for depositing and forming multiple thin-film toroidal inductors in the same sheet, in accordance with some embodiments;

FIG. 27 illustrates, in flow chart form, a fabrication method of the fabrication process for depositing and forming multiple thin-film toroidal inductors in the same sheet as illustrated in FIG. 26, in accordance with some embodiments;

FIG. 28 illustrates, in diagrammatic form, a cut-away side view of another fabrication process for depositing and forming multiple thin-film toroidal inductors in the same sheet, in accordance with some embodiments;

FIG. 29 illustrates, in flow chart form, a fabrication method of the fabrication process for depositing and forming multiple thin-film toroidal inductors in the same sheet as illustrated in FIG. 28, in accordance with some embodiments;

FIG. 30 illustrates, in diagrammatic form, a cut-away side view of a substrate core with embedded capacitors and inductors in accordance with some embodiments;

FIG. 31 illustrates, in diagrammatic form, a cut-away side view of another substrate core with embedded capacitors, inductors, and die, in accordance with some embodiments;

FIG. 32 illustrates, in isometric form, an exemplary vertically coupled inductor module, in accordance with some embodiments;

FIG. 33 illustrates, in diagrammatic form, a top cut-away view of another vertically coupled inductor module, in accordance with some embodiments;

FIG. 34 illustrates, in diagrammatic form, a top cut-away view of another vertically coupled inductor module, in accordance with some embodiments;

FIG. 35 illustrates, in diagrammatic form, a side view of a helical inductors, in accordance with some embodiments;

FIG. 36 illustrates, in isometric form, a side view of the helical inductor of FIG. 35, in accordance with some embodiments; and

FIG. 37 illustrates, in flow chart form, a method for forming the helical inductors of FIG. 35 and FIG. 36, in accordance with some embodiments.

### DETAILED DESCRIPTION

Continued pressure for electronic devices that provide greater functionality in ever-smaller form-factors is driving a trend for passive and active components being embedded within semiconductor package substrates or within printed circuit board (“PCB”) substrates. Passive components such as inductors(s) embedded in a semiconductor substrate or PCB may be used in power delivery (DC-DC conversion) or other filtering applications. These inductors may be integrated in the AC/DC substrate. An AC/DC substrate is a semiconductor package substrate that: (i) may have a few fine-pitch routing layers, primarily for interconnecting various dies on one surface of the semiconductor package substrate; (ii) has a few coarse-pitch routing layers, primarily for power and input and output (“IO”) connections to a PCB; and (iii) embedded device(s) in the core. The embedded device(s) may include devices such as capacitors, inductors, power, RF, digital, photonic dies, etc. These embedded devices may be used for filtering power noise, convert and regulate voltage, assist die-to-die communication, etc. The embedded devices may be bare devices or could be pre-formed modules of one or more bare devices.

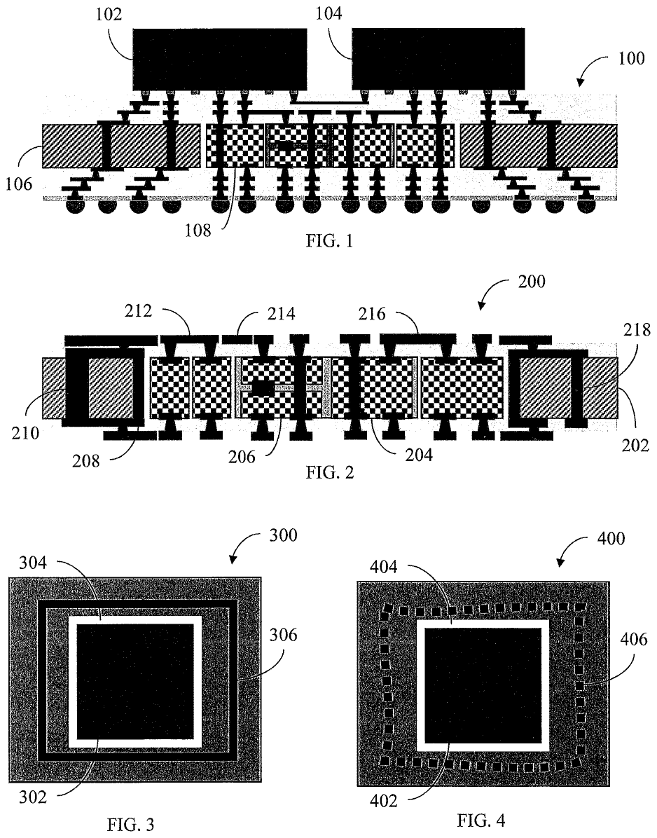

FIG. 1 illustrates, in diagrammatic form, a cut-away side view of an IC package substrate 100 in accordance with some embodiments. IC package substrate 100 is illustrated with die 102 and die 104 mounted on top and connected to the substrate utilizing a few fine-pitch routing layers along with a few coarse-pitch routing layers on the top side of the substrate core 106. IC package substrate 100 also includes substrate core 106 and modular passive device 108. Modular passive device 108 may be a modular inductor designed and manufactured or a module of inductor and capacitor to be embeddable in substrate core 106. IC package substrate 100 also illustrate course-pitch routing on the bottom side of the substrate core 106. The course-pitch routing layer on the bottom of IC package substrate 100 is adapted to connect the IC to a PCB or other platform.

FIG. 2 illustrates, in diagrammatic form, a cut-away side view of a package substrate 200 using package substrate redistribution layers (“RDL”) traces, in accordance with some embodiments. Package substrate 200 includes package substrate core 202 and various embedded inductors 204 placed within a cavity. As is well understood by those of ordinary skill in this area of electronic design, inductors have many parasitics associated with them that may impact signal integrity in sensitive digital and analog circuits, and they have a propensity to become coupled with other inductors. For embeddable inductor modules such as those described herein, the RDL traces may be utilized to provide parasitic shielding of the inductors as well as connectivity between the embeddable modular inductors and with other embeddable passive devices. Referring back to FIG. 2, as illustrated, various uses of package substrate RDL may include parasitic shielding by way of a metal sidewall 208 deposited on the inner wall of the cavity, or by way of a metallic trench 210 deposited in the substrate core material. Additional parasitic shielding may be provided by way of metal fill shielding 214 or via the use of plated through holes (“PTH”) 218. Connectivity between other embeddable inductors or other passive devices may be accomplished by way of package RDL 212 and RDL 216. Other embodiments are anticipated.

FIG. 3 illustrates, in diagrammatic form, a top view of a package substrate 300 using package substrate RDL layers traces, in accordance with some embodiments. Package substrate 300 includes embedded inductors 302 inside cavity 304. In this embodiment, package substrate 300 includes metallic trench 306 disposed during the RDL process to provide parasitic shielding from the electro-magnetic interference (“EMI”) produced by the embedded inductors. Similarly, FIG. 4 illustrates, in diagrammatic form, a top view of a package substrate 400 using package substrate RDL layers traces, in accordance with some embodiments. Package substrate 400 includes embedded inductors 402 inside cavity 404. In this embodiment, package substrate 400 includes PTH cage 406 disposed in a substantially linear array around the cavity 404 during the RDL process to provide parasitic shielding from the electro-magnetic interference (“EMI”) produced by the embedded inductors.

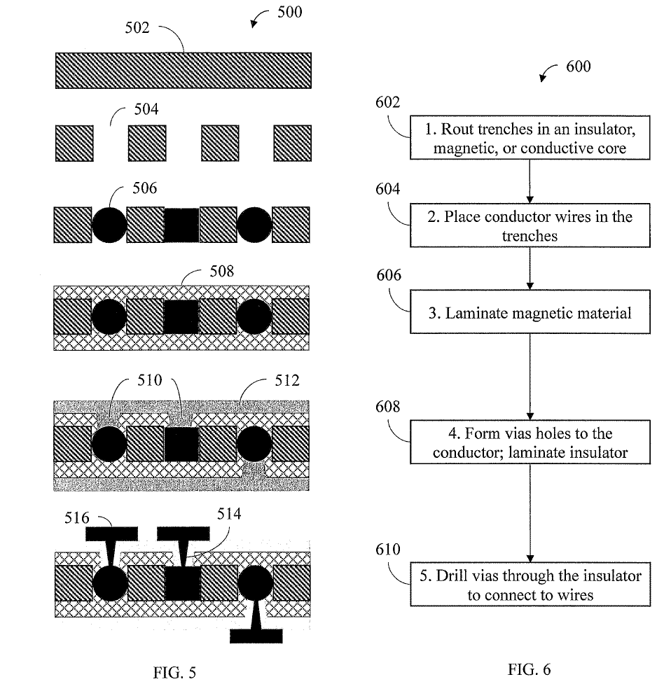

Traditional thin-film strip inductors use rectangular metal traces since they are easier to fabricate using existing metallization techniques. Cylindrical wires, while harder to fabricate, offer higher inductance per unit length for the same wire width. FIG. 5 illustrates, in diagrammatic form, a cut-away side view of a fabrication process of a thin-film strip inductor using cylindrical and rectangular wires in a thin-film form, in accordance with some embodiments. FIG. 6 illustrates, in flow chart form, a fabrication method of the fabrication process of a thin-film strip inductor using cylindrical and rectangular wires in a thin-film form as illustrated in FIG. 5, in accordance with some embodiments. In FIG. 5, trenches 504 are routed in a substrate core 502 (see FIGS. 6, 602). Substrate core 502 may be of an insulative material, a magnetic material, or a conductive material. Trenches in the substrate core 502 maintain the linearity of the wires to be deposited later as well as providing warpage control to the inductor sheet once formed. Such materials will be familiar to those skilled in the art of thin-film technology.

Coated conductor wires 506 are next placed in the trenches 504 (see FIGS. 6, 604). These coated conductor wires 506 may be spooled through these trenches or may be picked and placed. Coated conductor wires 506 may be cylindrical or rectangular, as illustrated in FIG. 5. The coating on the conductor wires serves the purposes of electrical insulation from a conductive or magnetic core, and/or protect the conductor from corrosion or oxidation. Common coating materials include Polyimide, Organic Solderability Preservative (OSP), Parylene, etc. Next, a magnetic material 508 is laminated onto the substrate core 502 and the coated conductor wires 506 (see FIGS. 6, 606). Next, via holes 510 are formed through the magnetic material 508 to the respective coated conductor wires 506 providing access to the coated conductor wires 506 through the magnetic material 508 (see FIGS. 6, 608). Formation of the via holes 510 may take place through the use of a device which may include a mechanical means, such as a mechanical drill, or an electromagnetic device, such as a laser for ablating substrate material. The via holes 510 through the magnetic material 508 may be further formed by way of a chemical etching process, such as a plasma etching process, the specifics of which are appreciated by those of ordinary skill in the art and are not further described herein.

An insulator 512 is deposited or laminated onto the magnetic material 508 and into the via holes 510 through the magnetic material 508 to the coated conductor wires 506 (see FIGS. 6, 608). Laminated insulator 512 is typically a material having a low permittivity that is more easily drilled through laser drilling methods than materials such as glass fiber reinforced epoxy resins and is deposited in the hole using standard packaging techniques, such as for example, squeegee printing or stencil printing with squeegee.

Via holes 514 are drilled through laminated insulator 512 to the coated conductor wires 506. Conductive material 516 is deposited in via holes 514, forming a connection with coated conductor wires 506, and capped with the same conductive material (see FIGS. 6, 610). Capping typically is done as part of a patterning process. Conducting materials include metals such as copper, aluminum, solder, and tungsten. The conducting material may be deposited, by way of example, in the hole for PTH 112 by PVD, ECD, or electrical plating, for example.

The manufacturing process and method described above and illustrated in FIG. 5 and FIG. 6 enable the use of various wire sizes, shapes, and lengths in the same sheet. Thus, various arrangements of conductor wires 506 are anticipated. Likewise, the inductor could be based upon a single or multiple layers of magnetic sheets, and the inductor may be single sided or multiple sided in its construction.

Although cylindrical wires offer higher inductance per unit length for the same wire width, there are certain challenges in the process of forming vias onto a spherical surface of the wire. These challenges are exacerbated by alignment tolerances required for pick and place platform's via drill processes. Raising the challenges even further, it is well understood that some magnetic materials may also be incompatible with laser drilling. Magnetic materials used in some thin-film inductors may include, but not be limited to, ferromagnetic materials such as Nickel-Iron (Ni—Fe), Cobalt Tantalum Zirconium alloy (Co—Zr—Ta), Cobalt Niobium Zirconium (Co—Nb—Zr), Iron Hafnium Nitride alloy (Fe—Hf—N), and the like. These magnetic thin films might be formed by dispersing spherical particles or flake particles or a combination of spherical and flake particles of the magnetic materials in a binding polymer matrix epoxy resin.

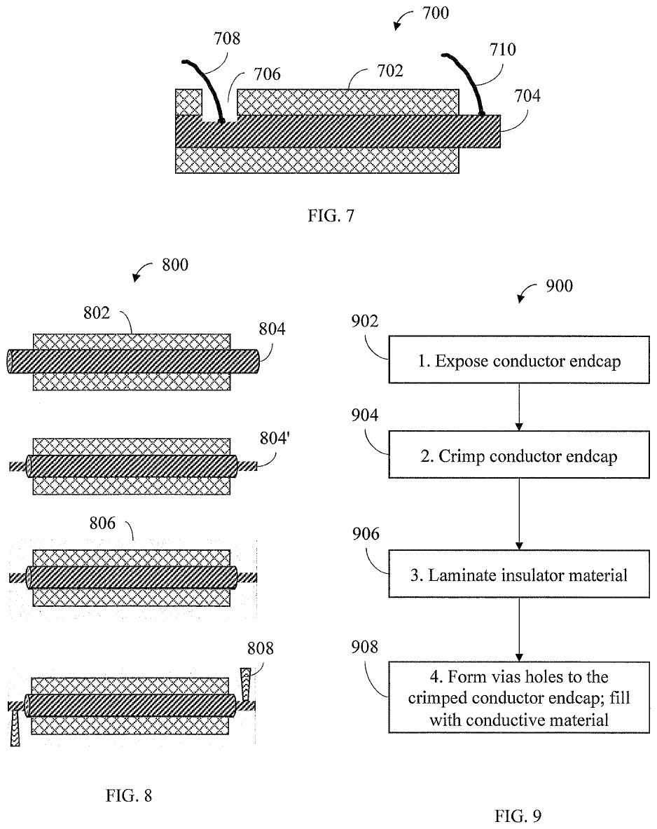

FIG. 7 illustrates, in diagrammatic form, a technique for connecting to an embedded pot core conductor within a thin film strip inductor 700, in accordance with some embodiments. Thin-film strip inductor 700 includes a magnetic material 702 and conductive cylindrical wire 704. Illustrated in FIG. 7, a first technique is to form a via hole 706 through the magnetic material 702 to the conductive cylindrical wire 704, providing a surface on the conductive cylindrical wire 704 available for a wire bond 708 to connect to the conductive cylindrical wire 704. Connections are typically formed by standard classes of wire bonding, e.g., ball bonding, wedge bonding, etc.

FIG. 8 illustrates, in diagrammatic form, a cut-away side view of a technique for connecting to an embedded pot core conductor within a thin film strip inductor 800, in accordance with some embodiments. FIG. 9 illustrates, in flow chart form, a method of connecting to an embedded pot core conductor within a thin film strip inductor 800 as illustrated in FIG. 8, in accordance with some embodiments. In FIG. 8, endcaps of a conductive cylindrical wire 804 are exposed (see FIGS. 9, 902). Exposure may be accomplished during the fabrication process of thin film inductor 800, or by removing magnetic material 802 after the fabrication process. The exposed endcap of conductive cylindrical wire 804 may then be crimped or flattened forming crimped endcap 804′ (see FIGS. 9, 904). Flattening or crimping of conductive cylindrical wire 804 into crimped endcap 804′ provides a flat surface for facilitating the connections to later deposited via metals. The thin film strip inductor 800 is next laminated with an insulator material 806 (see FIGS. 9, 906). Laminated insulator 806 is typically a material having a low permittivity that is more easily drilled through laser drilling methods than materials such as glass fiber reinforced epoxy resins and is deposited in the hole using standard packaging techniques, such as for example, squeegee printing or stencil printing with squeegee. Via holes are formed through insulator material 806 to the crimped endcap 804′and filled with conductive material forming via 808 (see FIGS. 9, 908). The conductive material may be deposited using industry standard techniques such as physical vapor deposition (“PVD”), also known as sputtering, electrochemical deposition (“ECD”), conductive ink-fill techniques for metals, and similar well understood techniques. Conductive materials include metals such as copper, aluminum, solder, and tungsten.

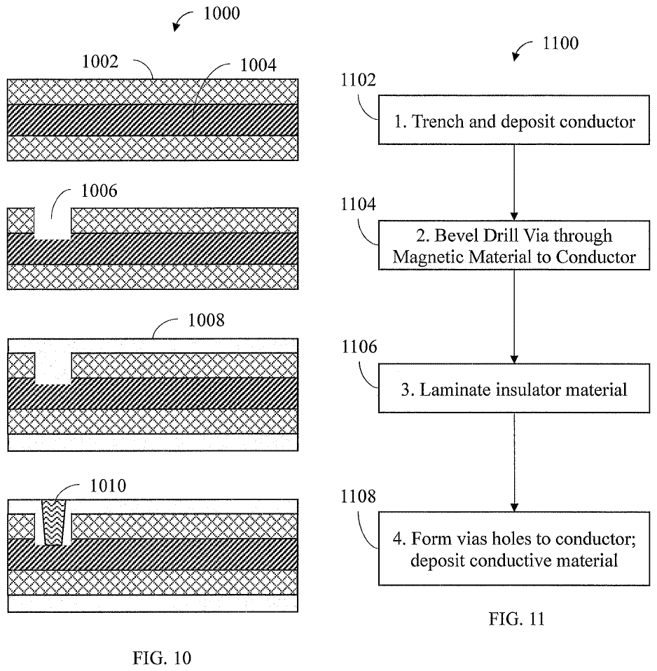

FIG. 10 illustrates, in diagrammatic form, a cut-away side view of a technique for connecting to an embedded pot core conductor within a thin film strip inductor 1000, in accordance with some embodiments. FIG. 11 illustrates, in flow chart form, a method of connecting to an embedded pot core conductor within a thin film strip inductor 1000 as illustrated in FIG. 10, in accordance with some embodiments. Thin film inductor 1000 includes magnetic material 1002 and conductive cylindrical wire 1004. Conductive cylindrical wire 1004 may be placed in trenches routed in magnetic material 1002 in inserting the conductive cylindrical wire 1004 as illustrated above in FIG. 5 (see FIGS. 11, 1102). A first via hole 1006 is formed by drilling though the magnetic material 1002 to conductive cylindrical wire 1004 (see FIGS. 11, 1104). Embedded pot core conductor 1000 is then laminated with an insulator material 1008 (see FIGS. 11, 1106). Next, via holes are formed through insulator material 1008 at first via hole 1006 to conductive cylindrical wire 1004 and deposit a conductive material forming via 1010 (see FIGS. 11, 1108).

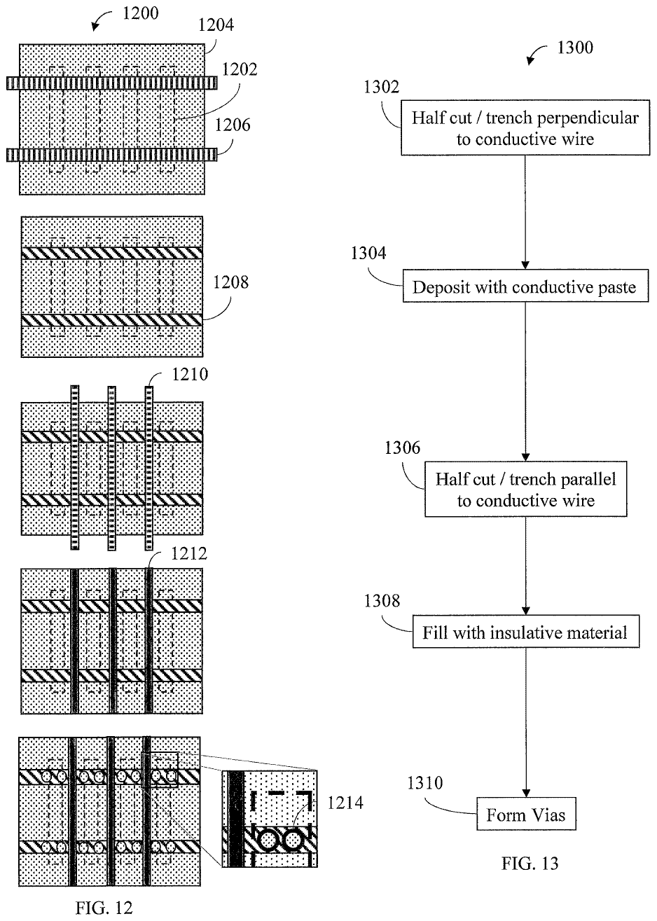

FIG. 12 illustrates, in diagrammatic form, a top view of a process 1200 for forming connections to and isolations between embedded pot core inductors on a sheet of embedded pot core inductors, in accordance with some embodiments. FIG. 13 illustrates, in flow chart form, a method 1300 for forming connections to and isolations between embedded pot core inductors on a sheet of embedded pot core inductors as illustrated in FIG. 12, in accordance with some embodiments. The sheet of embedded pot core in process 1200 includes a set of coated conductive wires 1202 having been formed in a magnetic core 1204 as discussed above in this disclosure. Trenches 1206 are formed perpendicular to the array of conductive wires 1202 (see FIGS. 13, 1302). Next, trenches 1206 are filed with a conductive material 1208 (see FIGS. 13, 1304). Conductive material 1208 may be deposited using industry standard techniques such as physical vapor deposition (“PVD”), also known as sputtering, electrochemical deposition (“ECD”), conductive ink-fill techniques for metals, and similar well understood techniques. Conductive material 1208 may include metals such as copper, aluminum, solder, tungsten, and other well understood conductive paste used in the semiconductor packaging industry. These half-cut trenches 1206 filled with conductive paste 1208 form connections to the underlying conductive wire 1202 embedded in the thin-film inductor. Referring back to FIG. 12, a second set of trenches 1210 are formed parallel to conductive wires 1202 (see FIGS. 13, 1306). Trenches 1210 are then filled with an insulative material 1212 (see FIGS. 13, 1308). This insulative material 1212 may be, but not limited to, a material such as Ajinomoto build up films (“ABF”) or other analogous thin-film insulative materials. Vias 1214 are then formed, providing connections to the underlying conductive wires 1202 (see FIGS. 13, 1310). The processes and techniques described may be used to form the connections from the embedded pot core conductor to the package/board wiring layers.

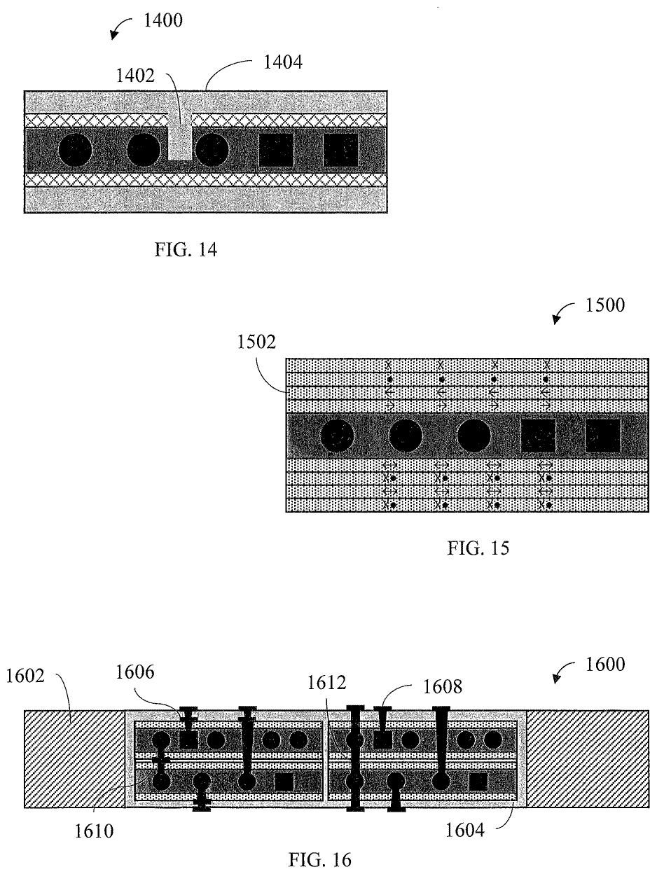

FIG. 14 illustrates, in diagrammatic form, a process 1400 of mitigating inductor coupling using trenching, in accordance with some embodiments. When multiple thin-film inductors are formed in sheets, the thin-film inductors are naturally coupled to one another by the magnetic material. Process 1400 illustrated the use of trench 1402 and the subsequent deposition of insulative material 1404 including depositing insulative material 1404 into the trench 1402. This insulative trench 1402 reduced the magnetic flux lines leading to a reduced coupling between thin film inductors. This is similar to air cavities in traditional magnets and magnetic materials. FIG. 15 illustrates, in diagrammatic form, a sheet of thin-film inductors 1500 using multi-layer thin-film sheets of magnetic material to alternate the flux direction of the thin-film inductors, in accordance with some embodiments. The sheet of thin-film inductors 1500 illustrates the stacking of multi-layer thin-film sheets 1502 with the direction of polarization alternating to effectively cancel the flux direction, thus reducing the coupling in the direction of coupling.

FIG. 16 illustrates, in diagrammatic form, exemplary stacked embedded inductors 1600 in a substrate core 1602, in accordance with some embodiments. Substrate core 1602 includes cavity 1604 into which multiple thin-film inductors are placed and stacked. Within the cavity 1604, stacking inductors increases both the number of inductors and/or inductance density by enabling a vertical serpentine. Multilayer inductors may be formed by stacking pre-formed pot core strip inductors as illustrated in FIG. 16, spooling wire layer-by-layer between magnetic sheets, or by microfabricating by plating the wires layer-by-layer with magnetic sheets as buildup layers, analogous to the fabrication processes utilized to build substrate and printed circuit boards. Connection terminals may be formed prior to embedding the inductors as illustrated by 1606, or may be formed after embedding the inductors as illustrated by 1608. Layers of inductors may be connected by forming the layer-to-layer connections prior to embedding as illustrated by 1610, or may be formed after the inductors are embedded in cavity 1604 as illustrated by 1612. Other embodiments and configurations of embedded inductors are anticipated such as the cavity having inductors in different layers not connected to each other or coupled to each other. Although thin-film strip pot core inductors are illustrated, inductors of other types may be utilized such as coil inductors, toroidal inductors, etc.

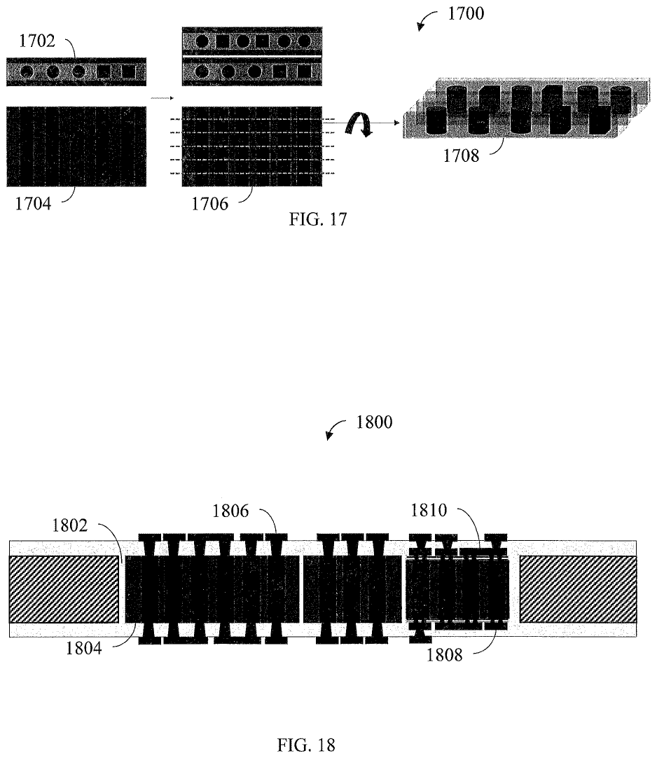

FIG. 17 illustrates, in diagrammatic form, a process for using pot-core strip inductors to build vertical inductors, in accordance with some embodiments. The exemplary vertical inductor process 1700 begins with forming pot-core strip inductors as discussed above in this disclosure. Pot-core strip inductor 1702 is a side cut view of the thin film pot-core strip inductor illustrated at 1704. By way of example only, these pot-core strip inductors may be formed by the process discussed in FIG. 5. Referring back to FIG. 17, once formed, pot-core strip inductor 1704 may be cut orthogonal to the conductive wires as illustrated at 1706. Illustrated at 1708 is a single slice of the pot-core strip inductor turned 90 degrees. FIG. 18 illustrates, in diagrammatic form, a substrate core 1800 with vertical inductors 1802 embedded in cavity 1804, in accordance with some embodiments. Embedding pot-core strip inductors formed as sheets in vertical inductors offers a number advantages, including, but not limited to: (a) there is no need to land the vias on cylindrical wire, the orthogonally cut pot-core strip inductor provides for a flat surface against which the via may be landed; (b) the input and output of the inductor can be closer to each other, as opposed to stacked pot-core strip inductors embedded in the horizontal orientation; and (c) the input and output existing on different sides simplifies routing. The sheets need not be stacked if a single linear array of pot-core strip inductors is chosen. Stacking allows a 2-dimensional array of embedded vertical inductors. The terminal metal 1806 is formed after embedding the vertical pot-core inductor. The terminal meal 1808 may be formed before embedding the vertical pot-core inductor 1804. Package RDL 1810 may be used to make contact to the conductor, and also to chain different sections of the inductors to form a longer serpentine inductor.

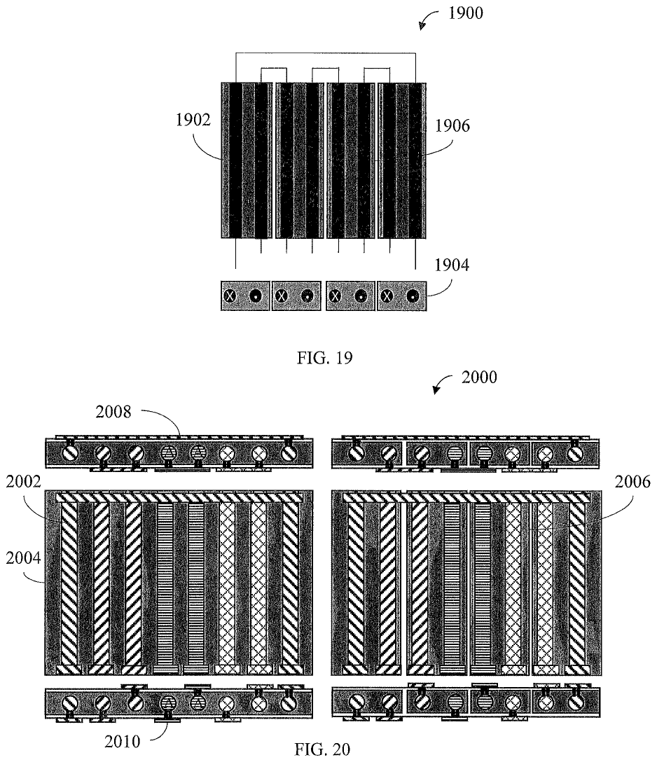

FIG. 19 illustrates, in diagrammatic form, an exemplary N-racetrack coupled pot-core strip inductor 1900, in accordance with some embodiments. In accordance with earlier processes and methods, exemplary pot-core strip inductor 1900 includes coated conductive wires 1902 embedded in a magnetic core 1904. Some portions of exemplary pot-core strip inductor 1900 are separated by trench isolation 1906 in accordance with the methods and processes disclosed above to manage the magnetic flux lines leading to a reduced coupling between thin film inductors. FIG. 20 illustrates, in diagrammatic form, other exemplary N-racetrack coupled pot-core strip inductor 2000, in accordance with some embodiments. In accordance with earlier processes and methods, exemplary pot-core strip inductor 2000 includes coated conductive wires 2002 embedded in a magnetic core 2004. Some portions of exemplary pot-core strip inductor 2000 are separated by trench isolation 2006 in accordance with the methods and processes disclosed above to manage the magnetic flux lines leading to a reduced coupling between thin film inductors. FIG. 20 also illustrates the use of RDL to connect the various exemplary pot-core strip inductors. RDL 2008 is an example of using RDL to connect the outer pot-core strip inductor. Use of RDL 2010 to provide terminals to pot-core strip inductor marked here as “A”. Other optional uses of RDL are illustrated. The exemplary design may be 2, 3, 4 . . . N inductors coupled together.

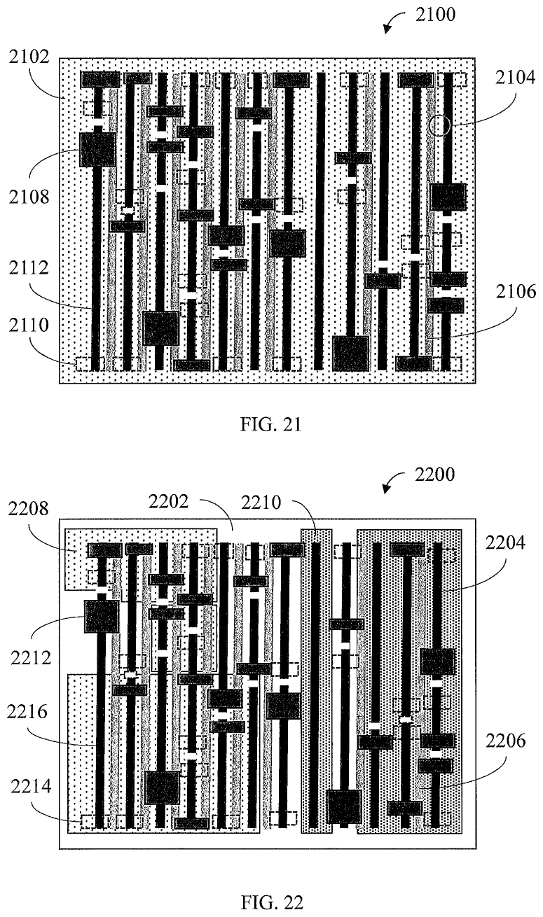

Forming the pot-core strip inductors as an array in a single sheet substantially simplifies the manufacturing of these pot-core strip inductors. An array of pot-core strip inductors in a single sheet provides for higher inductance density as compared to individualized and reconstituted inductors. Higher inductance density may be associated with an inherent inflexibility in designing inductors of different values, as well as coupling coefficients to service different functions/voltage rails in the system. FIG. 21 illustrates, in diagrammatic form, a top view of a single sheet of pot core strip inductors 2100, in accordance with some embodiments. The single sheet of pot core strip inductors 2100 includes a single sheet of magnetic material 2102 and embedded with conductive wire 2104. Per the earlier discussion of reducing the magnetic flux lines between inductors leading to a reduced coupling between thin film inductors, single sheet of pot core strip inductors 2100 also includes the half-cut isolation trenches 2106 filled with insulative materials to control coupling. As illustrated, conductive wire 2104 may be sectioned to different lengths and may also have different spacing between them, thus providing varying values of inductance and coupling coefficients. The single sheet of pot core strip inductors 2100 includes landing pads for various inductors. By way of example, single sheet of pot core strip inductors 2100 includes top inductor landing pad 2108 and bottom inductor landing pad 2110, providing terminals for inductor 2112. It is also anticipated that single sheet of pot core strip inductors 2100 may include shielding, passthrough PTHs, and the like.

FIG. 22 illustrates, in diagrammatic form, a top view of a single sheet of pot core strip inductors 2200, in accordance with some embodiments. The single sheet of pot core strip inductors 2200 includes a single sheet of thin-film material 2202 and embedded with conductive wire 2204. Per the earlier discussion of reducing the magnetic flux lines between inductors leading to a reduced coupling between thin film inductors, single sheet of pot core strip inductors 2200 also includes the half-cut isolation trenches 2206 filled with insulative materials to control coupling. The single sheet of pot core strip inductors 2200 also includes magnetic materials 2201 and 2210, each with different ferromagnetic characteristics providing for different inductance densities, saturation currents, etc. in different sections of the single sheet. As illustrated, conductive wire 2204 may be sectioned to different lengths and may also have different spacing between them, thus providing varying values of inductance and coupling coefficients. The single sheet of pot core strip inductors 2200 includes landing pads for various inductors. By way of example, single sheet of pot core strip inductors 2200 includes top inductor landing pad 2212 and bottom inductor landing pad 2214, providing terminals for inductor 2216.

The magnetic material may be patterned as illustrated in FIG. 22 creating a single final sheet with many irregular shapes. Each patterned sheet may include two or more magnetic materials which allow for the creation of different inductance densities, saturation currents, etc. at different sections of the module. The patterning and isolation of the magnetic materials may also allow for the design of the coupling, shielding, intensity, etc. of the flux pattern providing design flexibility.

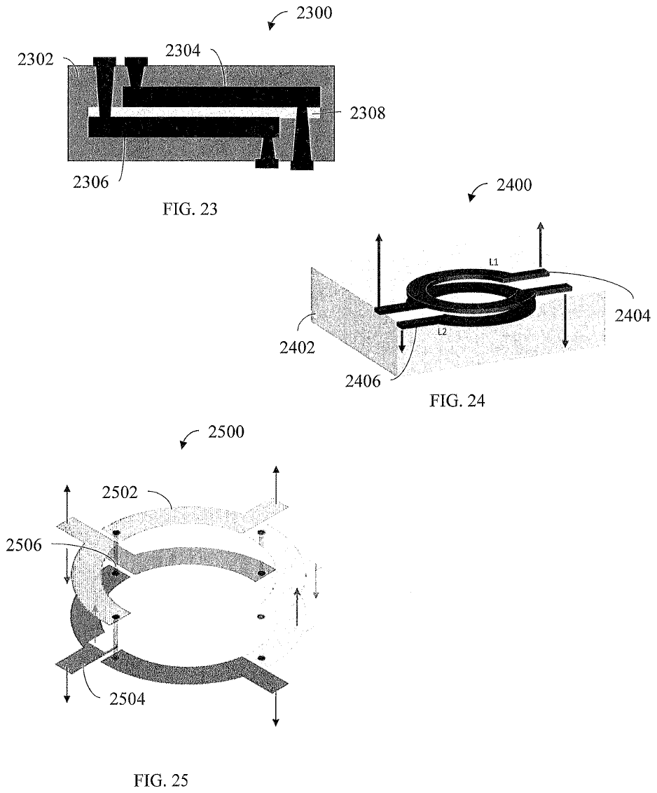

FIG. 23 illustrates, in diagrammatic form, an exemplary multi-layer pot-core coil inductor 2300, in accordance with some embodiments. Multi-layer pot-core coil inductor 2300 include magnetic substrate 2302, a first conductive wire 2304, and a second conductive wire 2306 deposited on a second layer. The first conductive wire 2304 and the second conductive wire 2306 are separated by the formation of an insulative layer 2308. Vias are formed as previously discussed above providing terminals to the inductor formed in this exemplary multi-layer pot-core coil inductor 2300.

FIG. 24 illustrates, in diagrammatic form, a different exemplary multi-layer pot-core coil inductor 2400, in accordance with some embodiments. Multi-layer pot-core coil inductor 2400 is a 2× coupled inductor. Multi-layer pot-core coil inductor 2400 includes insulative substrate 2402, a first conductive wire 2404, and a second conductive wire 2406 deposited on a second layer. Vias, represented in this diagram as the directional arrows from the respective ends of the first conductive wire 2404 and second conductive wire 2406, are formed as previously discussed above providing terminals to the inductor formed in this exemplary multi-layer pot-core coil inductor 2400.

FIG. 25 illustrates, in diagrammatic form, a different exemplary multi-layer pot-core coil inductor 2500, in accordance with some embodiments. Multi-layer pot-core coil inductor 2500 is a 4× coupled inductor. Multi-layer pot-core coil inductor 2500 include insulative substrate (not shown), a first conductive wire 2502 formed on the first wiring layer, and a second conductive wire 2504 formed on a second wiring layer. Vias, represented in this diagram as the directional arrows from the respective ends of the first conductive wire 2502 and second conductive wire 2504, are formed as previously discussed above providing terminals to the inductor formed in this exemplary multi-layer pot-core coil inductor 2500. Vias 25XX between the first and second wiring layers provide connection between the two sections of an inductor across the two wiring layers. The magnetic substrate is not shown in this illustration.

FIG. 24 and FIG. 25 illustrate 2x and 4x coupled inductors in a multiple conductor layers. The up arrows and down arrows represent vias to the top and bottom side terminals of the inductor respectively. Alternatively, these inductors may also have only terminals on the same side. In the 4X coupled inductors, the coils may be inwards or outwards.

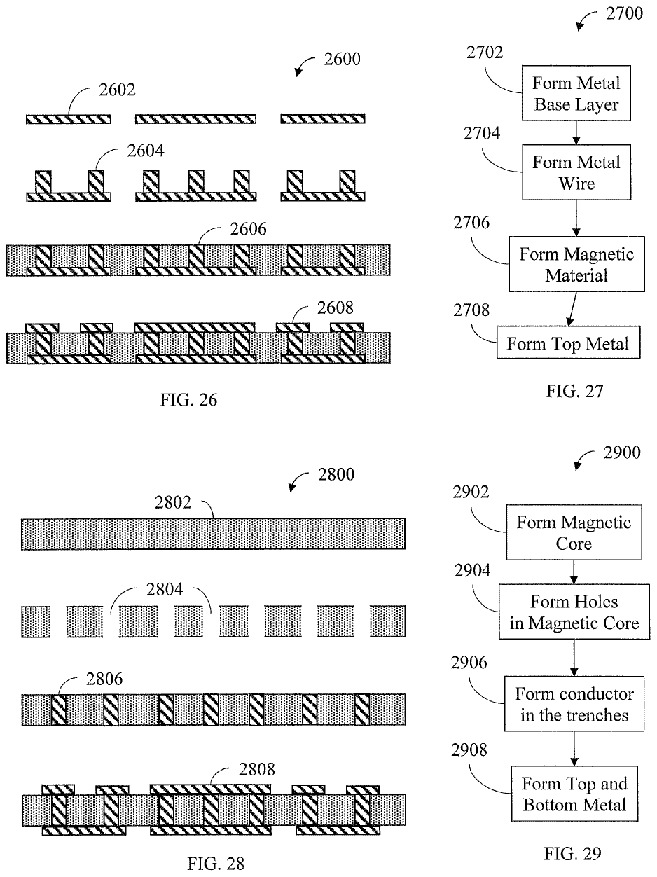

FIG. 26 illustrates, in diagrammatic form, a cut-away side view of a fabrication process 2600 for depositing and forming multiple thin-film toroidal inductors in the same sheet, in accordance with some embodiments. FIG. 27 illustrates, in flow chart form, a fabrication method 2700 of the fabrication process 2600 for depositing and forming multiple thin-film toroidal inductors in the same sheet as illustrated in FIG. 26, in accordance with some embodiments. Fabrication process 2600 begins with the formation of a metal base layer 2602 (see FIGS. 27, 2702). Metal wires 2604 are subsequently formed onto the metal base layer 2602 (see FIGS. 27, 2704). Magnetic material 2606 is next formed (see FIGS. 27, 2706), followed by a top metal 2608 (see FIGS. 27, 2706). The magnetic material may be formed by processes such as lamination, compression molding, casting, etc. As mentioned earlier, the magnetic material may also be composite of sphere/flake/combination of sphere and flake magnetic particles dispersed in a polymeric matrix. Top metal 2608 may be by way of RDL layers or by deposition such as micro-sputtering, etc.

FIG. 28 illustrates, in diagrammatic form, a cut-away side view of another fabrication process 2800 for depositing and forming multiple thin-film toroidal inductors in the same sheet, in accordance with some embodiments. FIG. 29 illustrates, in flow chart form, a fabrication method 2900 of the fabrication process 2800 for depositing and forming multiple thin-film toroidal inductors in the same sheet as illustrated in FIG. 28, in accordance with some embodiments. Fabrication process 2800 begins with the formation of magnetic core material 2802 (see FIGS. 29, 2902). The magnetic material may be formed by processes such as lamination, compression molding, casting, etc. As mentioned earlier, the magnetic material may also be composite of sphere/flake/combination of sphere and flake magnetic particles dispersed in a polymeric matrix. Holes 2804 are formed in the magnetic core material 2802 as described above in this disclosure (see FIGS. 29, 2904). Conductors 2806 may formed in the holes 2804 (see FIGS. 29, 2906). The final step is forming top and bottom metal 2808 (see FIGS. 29, 2908). Top and bottom metals may be by way of RDL layers or by deposition such as micro-sputtering, electroplating, or by laminating metal foil followed by patterned etching, etc.

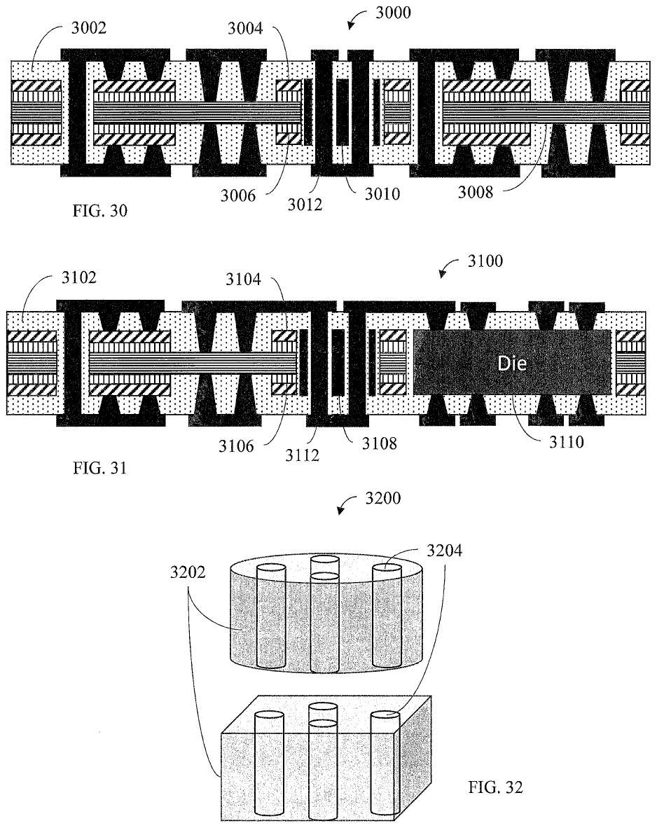

FIG. 30 illustrates, in diagrammatic form, a cut-away side view of a module 3000 with embedded capacitors and inductors in accordance with some embodiments. The various inductors described herein may be embedded with other components such as capacitors or die. Module 3000 includes insulator 3002, current collector 3004, dielectric 3006, and capacitor core 3008. Module 3000 also includes the magnetic material 3010 of the inductor integrated in substrate core 3000. Vertical conductor 3012 through the magnetic material 3010 forms the inductor. The inductor may also serpentine through the magnetic material by utilizing the RDL conductor on top and/or bottom side. FIG. 31 illustrates, in diagrammatic form, a cut-away side view of another substrate core 3100 with embedded capacitors, inductors, and die, in accordance with some embodiments. Module 3100 includes insulator 3102, current collector 3104, dielectric 3106, and the capacitor core. Module 3100 also include the magnetic material 3010 of the inductor integrated in substrate core 3000. Vertical conductor 3112 through the magnetic material 3010 forms the inductor. The inductor may also serpentine through the magnetic material by utilizing the RDL conductor on top and/or bottom side. Module 3000 also includes a die 3110 embedded with the capacitor and inductor and demonstrates the use of RDL to connect the elements with die 3110. Shielding, passthrough PTHs, etc. can be built into a single embedded module. This provides for the power management integrated circuit may be embedded in another trench in the capacitor to form a thin-film embedded voltage regulator module where the terminal metals may be used to form the necessary connections.

FIG. 32 illustrates, in isometric form, an exemplary vertically coupled inductor module 3200, in accordance with some embodiments. Vertically coupled inductor module 3200 includes magnetic material 3202 and vertically oriented conductive wires 3204 embedded in magnetic material 3202. The exemplary vertically coupled inductor module 3200 may be formed as a cylinder or as a cube as illustrated in FIG. 32.

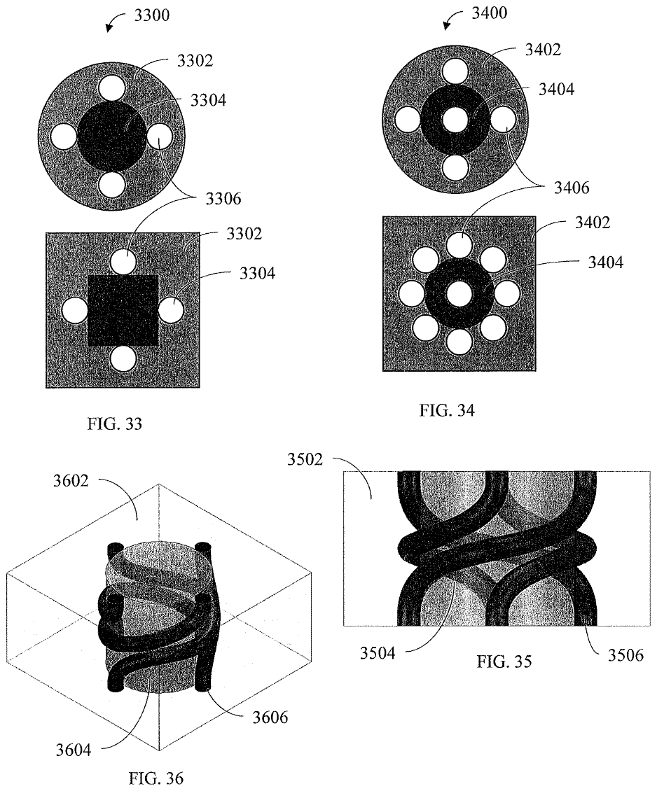

FIG. 33 illustrates, in diagrammatic form, a top cut-away view of another vertically coupled inductor module 3300, in accordance with some embodiments. Vertically coupled inductor module 3300 includes magnetic material 3302 as well as a second magnetic material 3304. Vertically oriented conductive wires 3306 embedded in magnetic material 3302 surround the second magnetic material 3304. The exemplary vertically coupled inductor module 3300 may be formed as a cylinder or as a cube as illustrated in FIG. 33.

FIG. 34 illustrates, in diagrammatic form, a top cut-away view of another vertically coupled inductor module 3400, in accordance with some embodiments. Vertically coupled inductor module 3300 includes magnetic material 3402 as well as a second magnetic material 3404. Vertically oriented conductive wires 3406 embedded in magnetic material 3402 surround the second magnetic material 3404. In this example, another vertically oriented conductive wire may be embedded in the second magnetic material 3404. The exemplary vertically coupled inductor module 3400 may be formed as a cylinder or as a cube as illustrated in FIG. 34.

The multilayer coupled inductors disclosed above are limited by the number of available metal layers that may be packed in a given unit area. The spatial limitations around vias to transition from one layer to another also limits the coupling efficiency. Planar structure may also be limited by microfabrication techniques which are only suited for planar structures and are inefficient for 3-dimensional structures. Planar inductors are therefore generally less efficient in comparison to 3-dimensional structures such as coils and the like. FIG. 35 illustrates, in diagrammatic form, a side view of a helical inductors, in accordance with some embodiments. The helical inductor of FIG. 35 includes a first magnetic material 3502, a second magnetic material 3504, and a plurality of conductive wires 3506 formed in a helical formation around the second magnetic material 3504 and through the first magnetic material 3502. These structures may be built using spooling techniques and thereby not limited by a number of metal layers. These helical inductors are compatible with embedding into substrate cores. The helical inductor of FIG. 35 is exposed on the top and bottom, exposing the end-cap of conductive wires 3506 as terminal metal connection points. FIG. 36 illustrates, in isometric form, a side view of the helical inductor of FIG. 35, in accordance with some embodiments. The helical inductor of FIG. 36 includes a first magnetic material 3602, a second magnetic material 3604, and a plurality of conductive wires 3606 formed in a helical formation around the second magnetic material 3604 and through the first magnetic material 3602. For these helical inductors, there may be any number of conductor windings and thereby any number of coupled inductors. Magnetic materials 3502 and 3504 may be the same or different magnetic materials. Similarly, magnetic materials 3602 and 3604 may be the same or different magnetic materials. The conductor could be Cu, Al, Ag, Au, etc. Since the structure is fabricated by spooling the choice of conductor is not limited by microfabrication processes. A ½ turn coil is shown in the picture above, but each inductor may have any number of turns, e.g., ¼, ¾, 2, etc., and each module may include inductors with a combination of different turn counts. Because the helical inductors are fabricated by spooling, they may be cylindrical, cuboidal, or any other 3-dimentional geometrical shape. The conductive wires may be coated with an insulator to avoid shorting depending on the choice of magnet used.

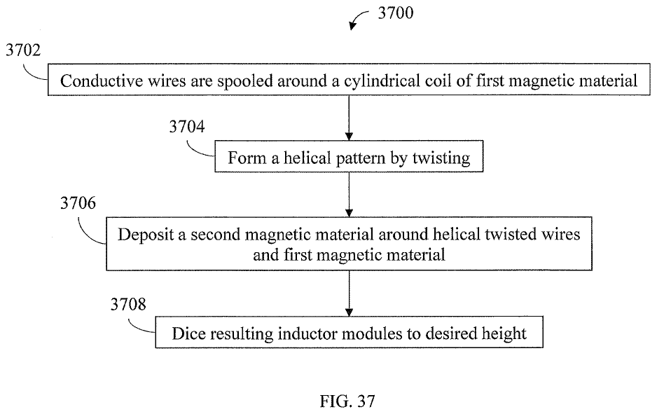

FIG. 37 illustrates, in flow chart form, a method for forming the helical inductors 3700 of FIG. 35 and FIG. 36, in accordance with some embodiments. The method for forming helical inductors 3700 begins with spooling conductive wires around a cylindrical coil of a first magnetic material (see FIGS. 37, 3702). The conductive wires may be coated in insulative material. A helical pattern is formed by twisting the conductive wires (see FIGS. 37, 3704). The twisting is controlled so that the conductive wires are properly spaced from one another. Next, a second magnetic material is deposited around the first magnetic material and the helically twisted conductive wires (see FIGS. 37, 3706). The deposition process may be one of lamination, or by molding. After curing, the helical inductor is diced into smaller modules to a desired height to facilitate embedding in the cavity of a substrate core (see FIGS. 37, 3708). Dicing ensures the conductive wires are exposed for the adding of terminal metal and the like.

Thus, it will be apparent to one of ordinary skill that this disclosure provides for improved method and apparatus for use in semiconductor packaging substrates, and in particular to improve the performance and reduce the area utilized by embedded inductors in semiconductor packaging substrates.

Apparatus, methods and systems according to embodiments of the disclosure are described. Although specific embodiments are illustrated and described herein, it will be appreciated by those of ordinary skill in the art that any arrangement which is calculated to achieve the same purposes can be substituted for the specific embodiments shown. This application is intended to cover any adaptations or variations of the embodiments and disclosure. For example, although described in terminology and terms common to the field of art, exemplary embodiments, systems, methods and apparatus described herein, one of ordinary skill in the art will appreciate that implementations can be made for other fields of art, systems, apparatus or methods that provide the required functions. The invention should therefore not be limited by the above-described embodiment, method, and examples, but by all embodiments and methods within the scope and spirit of the invention.

In particular, one of ordinary skill in the art will readily appreciate that the names of the methods and apparatus are not intended to limit embodiments or the disclosure. Furthermore, additional methods, steps, and apparatus can be added to the components, functions can be rearranged among the components, and new components to correspond to future enhancements and physical devices used in embodiments can be introduced without departing from the scope of embodiments and the disclosure. One of skill in the art will readily recognize that embodiments are applicable to future systems, future apparatus, future methods, and different materials.

All methods described herein can be performed in a suitable order unless otherwise indicated herein or otherwise clearly contradicted by context. The use of any and all examples, or exemplary language (e.g., “such as”), is intended merely to better illustrate the disclosure and does not pose a limitation on the scope of the disclosure unless otherwise claimed. No language in the specification should be construed as indicating any non-claimed element as essential to the practice of the disclosure as used herein.

Terminology used in the present disclosure is intended to include all environments and alternate technologies that provide the same functionality described herein.

1. An inductor adapted for use in a semiconductor package, said inductor comprising:
a substrate core;
a plurality of trenches in said substrate core;
a conductive material deposited in said plurality of trenches in said substrate core;
a first insulative layer on a first surface of said substrate core and a first surface of said conductive material deposited in said plurality of trenches in said substrate core;
an inductive pattern formed by at least:
a first via hole, beginning at a surface of said first insulative layer, through said first insulative layer, terminating at said first surface of said conductive material deposited in said plurality of trenches in said substrate core;
a second insulative layer on said surface of said first insulative layer and in said first via hole; and
a second via hole, beginning at a surface of said second insulative layer, through said second insulative layer, terminating at said first surface of said conductive material deposited in said plurality of trenches in said substrate core.

2. The method of claim 1, wherein said substrate core is further characterized as formed of a semiconductor material.

3. The method of claim 1, wherein said substrate core is further characterized as formed of a ferromagnetic material.

4. The method of claim 1, wherein said substrate core is further characterized as formed of an insulative material.

5. The method of claim 1, wherein said inductor pattern is a square spiral.

6. The method of claim 1, wherein said inductor pattern is a racetrack pot-core strip.

7. A sheet of thin-film pot-core inductors comprising:
a substrate core material;
a first magnetic material deposited on a portion of an area of said substrate core material;
a first plurality of inductors formed by a first plurality of trenches in said substrate core material and in said first magnetic material, said first plurality of trenches being filled with conductive material; and
a second plurality of trenches in said substrate core and in said first magnetic material, said second plurality of trenches being filled with insulative material; said second plurality of trenches being interleaved between said first plurality of trenches to control coupling between said first plurality of inductors.

8. The sheet of thin-film pot-core inductors of claim 7 further comprising:
a second magnetic material deposited on a portion of an area of said substrate core material different from said first magnetic material;
a second plurality of inductors formed by a second plurality of trenches in said substrate core material and in said second magnetic material, said second plurality of trenches being filled with conductive material; and
said second plurality of trenches being formed in in said substrate core material and in said second magnetic material, said second plurality of trenches being filled with insulative material; said second plurality of trenches being interleaved between said first plurality of trenches to control coupling between said second plurality of inductors.

9. The method of claim 7, wherein said substrate core is further characterized as formed of a semiconductor material.

10. The method of claim 7, wherein said substrate core is further characterized as formed of a ferromagnetic material.
